(19) United States
(12) Patent Application Publication
(10) Pub. No.: US 2005/0232443 A1
(43) Pub. Date: Oct. 20, 2005

(54) Machine for audio/video stereo receiver with multiple tone controls

(76) Inventor: Young Sun Lee, Los Angeles, CA (US)

Correspondence Address: YOUNG SUN LEE, 500 SOUTH CATALINA STREET #310, LOS ANGELES, CA, 90020, US

(21) Appl. No.: 10/827,124

(22) Filed: Apr. 19, 2004

(51) Int. Cl. H03G 5/00; H04B 1/00

(52) U.S. Cl. 381/101; 381/119

(57) ABSTRACT

A machine for Audio/Video Stereo Receiver with Multiple Tone Controls. In addition to the system power switch, master volume control and balance control, the front panel of the receiver is further divided into a number of component strip areas. Each component strip has its own tone controls—usually treble and bass. There is on/off switch on each component strip, to connect or disconnect to the main circuitry of the receiver. Component plug-ins, located in the back panel of the receiver, are positioned straight behind each component strip located in the front panel of the receiver. The back panel, where component plug-ins are located, is slanted (about 45 degrees), with the component plug-ins facing diagonally upward.

### CROSS REFERENCE TO RELATED APPLICATIONS

Not Applicable

### STATEMENT REGARDING FEDERALLY SPONSORED RESEARCH OR DEVELOPMENT

Not Applicable

### DESCRIPTION OF ATTACHED APPENDIX

Not Applicable

### BACKGROUND OF THE INVENTION

This invention relates generally to the field of consumer electronics and more specifically to a machine for Audio/Video Stereo Receiver with Multiple Tone Controls. In this new receiver design, separate tone control, usually treble and bass, is placed in the front panel for each of the connected component. The user now has to set the desired tone for each connected component only once. Also, the back panel, where component plug-in area is located, is slanted (about a 45 degree angle), with the panel facing upward diagonally. So the user can easily identify the correct plug-ins from all direction. Each component plug-in is situated straight behind each of the component's front panel strip. The result is that the job of connecting or disconnecting different components to the receiver has become easy and simple.

In all the existing stereo components, various input sources such as CD/DVD player, VCR, TV, etc., are connected to the receiver in the back panel. The tone of all these sound sources is controlled by a single set of equalizers in the front panel, usually treble and bass. But this kind of existing design necessitates undue efforts in adjusting the tone of various sound sources, which often demands distinctively different tones. For example, when listening to a music CD, strong bass sound is usually preferred. So the user steps over to the receiver and turns up the bass button. But when watching TV news and hearing the TV anchor's human voice, big bass sound makes the voice unnatural. Now, the user is very likely to step over to the receiver again and turn down the bass button. In other words, with existing receiver designs, the listener is likely to walk over and adjust the treble and bass every time a different type of source is heard, whether it be TV news, music CD, DVD movie or other. Also, the existing receivers are almost uniformly in square box shape. In this square box shape, the back panel, where component plug-ins are located, is perpendicular from either top or bottom of the receiver box. Consequently, each of the plug-ins is not easily visible separately by the user, who will normally look down at the receiver from a standing position. The user almost invariably has to step behind the receiver, which may usually be placed close to the wall, to locate the correct plug-ins for each component. This cumbersome and awkward work has to be done every time a different component is connected to the receiver.

### BRIEF SUMMARY OF THE INVENTION

The primary object of the invention is to provide a separate tone control—treble and bass—for each connected component.

Another object of the invention is to eliminate the necessity of having to adjust the tone every time a different component is heard.

Another object of the invention is to make the necessity of adjusting tone control for each connected component only once.

A further object of the invention is to make the work of connecting various components to the receiver easier, with a slanted back panel where component plug-ins are located.

Other objects and advantages of the present invention will become apparent from the following descriptions, taken in connection with the accompanying drawings, wherein, by way of illustration and example, an embodiment of the present invention is disclosed.

In accordance with a preferred embodiment of the invention, there is disclosed a machine for Audio/Video Stereo Receiver with Multiple Tone Controls that has features of: a. Front panel that includes a number of component strips, in addition to the traditional functions such as volume control, balance control and system on/off switch; and b. Back panel that is partly slanted.

### BRIEF DESCRIPTION OF THE DRAWINGS

The drawings constitute a part of this specification and include exemplary embodiments to the invention, which may be embodied in various forms. It is to be understood that in some instances various aspects of the invention may be shown exaggerated or enlarged to facilitate an understanding of the invention.

FIG. 1 is a front view of the invention.

FIG. 2 is a side view of the invention.

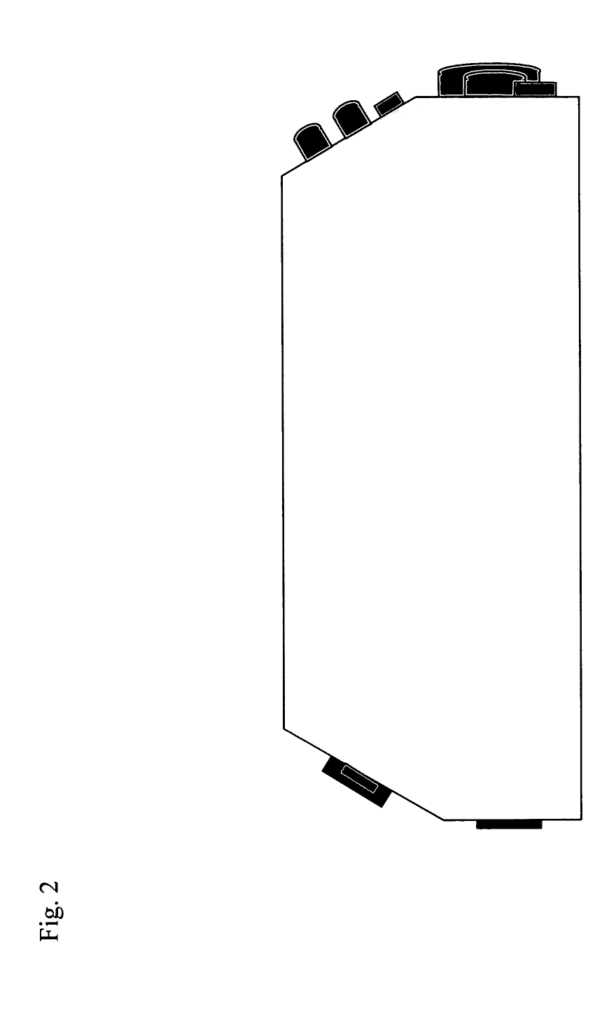

FIG. 3 is a back view of the invention.

FIG. 4 is a perspective view of the invention.

FIG. 5 is a front view of the invention, with various components connected along with loud speakers.

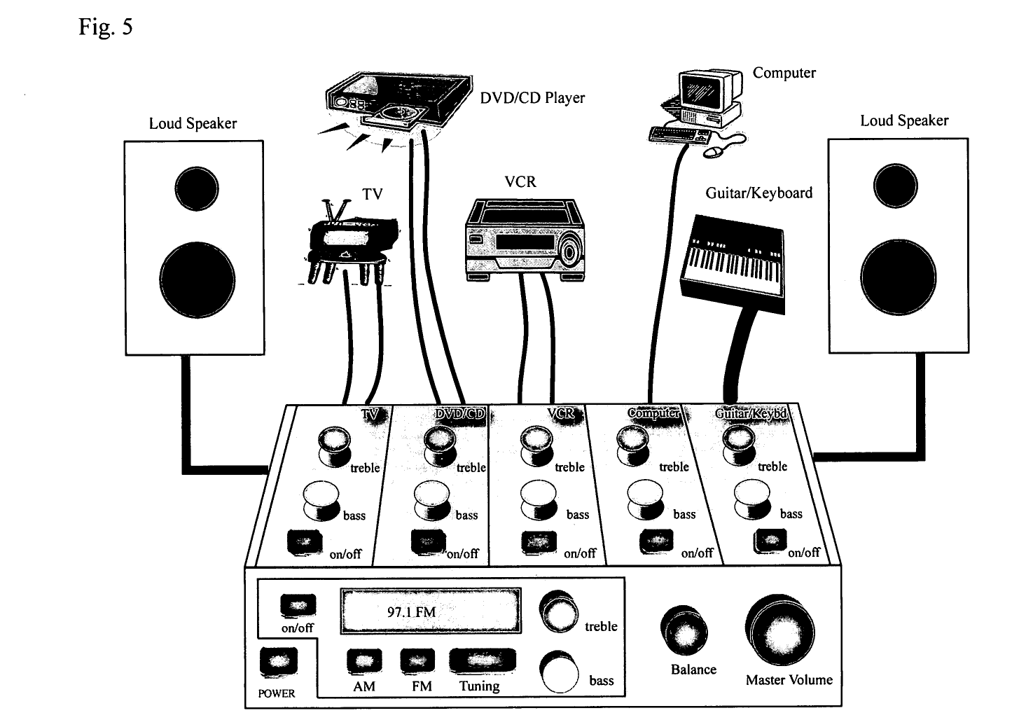

### DETAILED DESCRIPTION OF THE PREFERRED EMBODIMENTS

Detailed descriptions of the preferred embodiment are provided herein. It is to be understood, however, that the present invention may be embodied in various forms. Therefore, specific details disclosed herein are not to be interpreted as limiting, but rather as a basis for the claims and as a representative basis for teaching one skilled in the art to employ the present invention in virtually any appropriately detailed system, structure or manner.

In the machine for Audio/Video Stereo Receiver with Multiple Tone Controls:

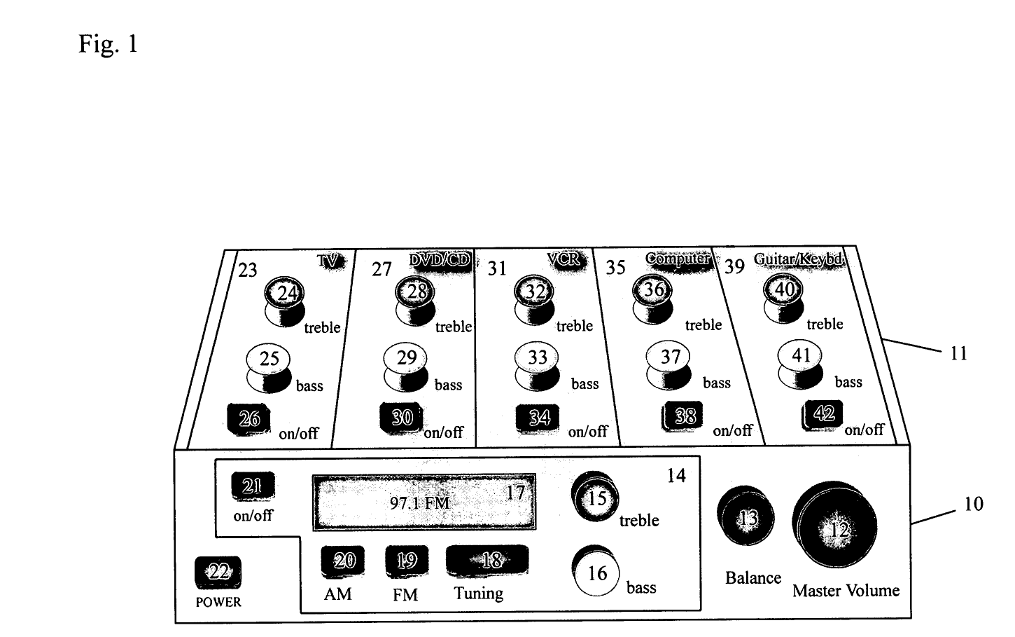

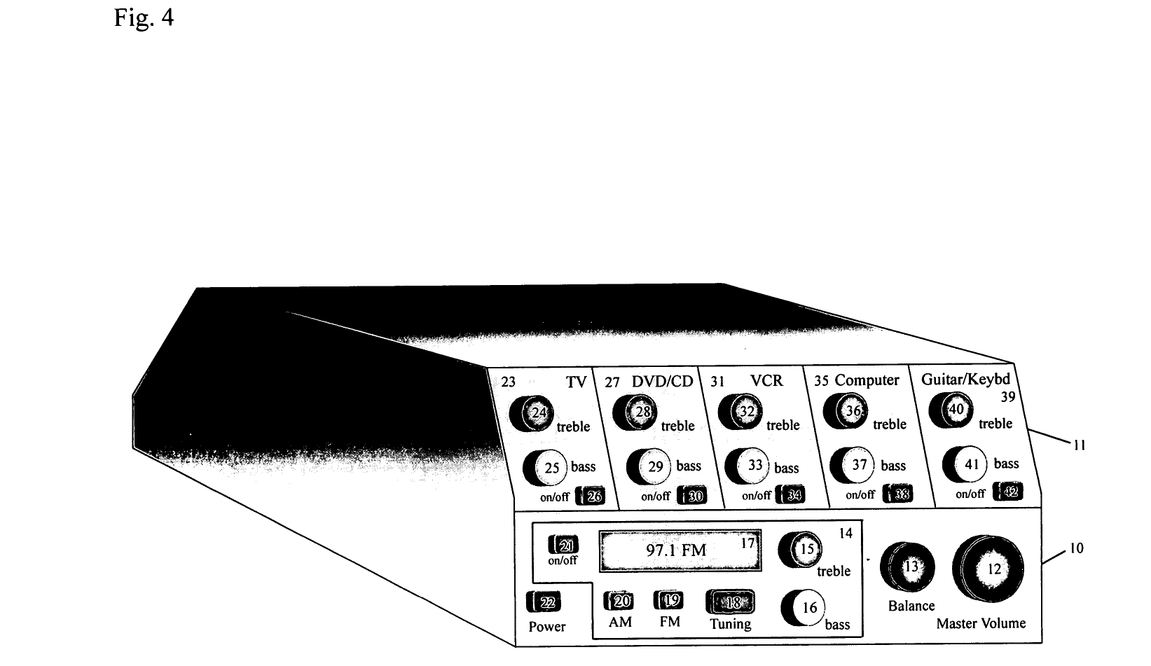

In FIG. 1 and FIG. 4,
10 is lower section of the front panel.
11 is upper section of the front panel.
12 is master volume control of the receiver
13 is balance control of the receiver. It pans the stereo sound of the connected component(s) to the loud speaker on the left or on the right.
14 is AM/FM radio strip.
15 is treble control button for the AM/FM radio strip. More high tone is produced if turned right and high tone is reduced if turned left.
16 is bass control button for the AM/FM radio strip. More low tone is produced if turned right and low tone is reduced if turned left.
17 is display for the selected radio station and other useful functions, such as selected component strips and clock.
18 is tuning control for AM/FM radio
19 is FM mode selection button. When pressed on, FM radio is selected. When pressed off, FM radio is deselected.
20 is AM radio selection button. When pressed on, AM radio is selected. When pressed off, AM radio is deselected.
21 is on/off switch for the AM/FM radio strip. When pressed on, AM/FM radio strip is turned on. It then activates the treble and bass controls of the AM/FM radio strip and connects the radio signals to the receiver's main circuitry, and sound is transmitted to the loud speakers that are connected to the speaker terminals in the receiver's back panel. When pressed off, AM/FM radio strip is turned off and deactivates the treble and bass controls of the AM/FM radio strip, and radio signals are disconnected from the receiver's main circuitry and no sound is transmitted to the loud speaker.
22 is system power on/off switch.
23 is first component strip, TV in this drawing. Using proper connecting material such as RCA cables, the audio outs of the TV can be hooked up to the appropriate inserts in the slanted plug-in area in the receiver's back panel.
24 is treble control button for the TV strip.
25 is bass control button for the TV strip.
26 is on/off switch for the TV strip. When pressed on, TV strip is turned on. It then activates the treble and bass controls of the TV strip, and connects sound signals coming from TV to the receiver's main circuitry, and sound is transmitted to the loud speakers that are connected to the speaker terminals in the receiver's back panel. When pressed off, TV strip is turned off and deactivates the treble and bass controls of the TV strip, and sound signals coming from TV are disconnected from the receiver's main circuitry and no sound is transmitted to the loud speaker.
27 is second component strip, DVD/CD in this drawing. Using proper connecting material such as RCA cables, the audio outs of the DVD/CD player can be hooked up to the appropriate inserts in the slanted plug-in area in the receiver's back panel.
28 is treble control button for the DVD/CD strip.
29 is bass control button for the DVD/CD strip.
30 is on/off switch for the DVD/CD strip. When pressed on, DVD/CD strip is turned on. It then activates the treble and bass controls of the DVD/CD strip, and connects sound signals coming from DVD/CD player to the receiver's main circuitry, and sound is transmitted to the loud speakers that are connected to the speaker terminals in the receiver's back panel. When pressed off, DVD/CD strip is turned off and deactivates the treble and bass controls of the DVD/CD strip, and sound signals coming from DVD/CD player are disconnected from the receiver's main circuitry and no sound is transmitted to the loud speaker.
31 is third component strip, VCR in this drawing. Using proper connecting material such as RCA cables, the audio outs of the VCR player can be hooked up to the appropriate inserts in the slanted plug-in area in the receiver's back panel.
32 is treble control button for the VCR strip.
33 is bass control button for the VCR strip.
34 is on/off switch for the VCR strip. When pressed on, VCR strip is turned on. It then activates the treble and bass controls of the VCR strip, and connects sound signals coming from VCR player to the receiver's main circuitry, and sound is transmitted to the loud speakers that are connected to the speaker terminals in the receiver's back panel. When pressed off, VCR strip is turned off and deactivates the treble and bass controls of the VCR strip, and sound signals coming from VCR player are disconnected from the receiver's main circuitry and no sound is transmitted to the loud speaker.
35 is fourth component strip, Computer in this drawing. Using proper connecting material such as 3.5 mm cable, the audio outs of the Computer can be hooked up to the appropriate insert in the slanted plug-in area in the receiver's back panel.
36 is treble control button for the Computer strip.
37 is bass control button for the Computer strip.
38 is on/off switch for the Computer strip. When pressed on, Computer strip is turned on. It then activates the treble and bass controls of the Computer strip, and connects sound signals coming from the main board or sound card of the Computer to the receiver's main circuitry, and sound is transmitted to the loud speakers that are connected to the speaker terminals in the receiver's back panel. When pressed off, Computer strip is turned off and deactivates the treble and bass controls of the Computer strip, and sound signals coming from Computer are disconnected from the receiver's main circuitry and no sound is transmitted to the loud speaker.
39 is fifth component strip, Guitar/Keyboard in this drawing. Using proper connecting material such as ¼ inch cable, the sound outs of the guitar or keyboard can be hooked up to the appropriate insert in the slanted plug-in area in the receiver's back panel.
40 is treble control button for the Guitar/Keyboard strip.
41 is bass control button for the Guitar/Keyboard strip.
42 is on/off switch for the Guitar/Keyboard strip. When pressed on, Guitar/Keyboard strip is turned on. It then activates the treble and bass controls of the Guitar/Keyboard strip, and connects sound signals coming from the guitar or keyboard to the receiver's main circuitry, and sound is transmitted to the loud speakers that are connected to the speaker terminals in the receiver's back panel. When pressed off, Guitar/Keyboard strip is turned off and deactivates the treble and bass controls of the Guitar/Keyboard strip, and sound signals coming from Guitar/Keyboard are disconnected from the receiver's main circuitry and no sound is transmitted to the loud speaker.

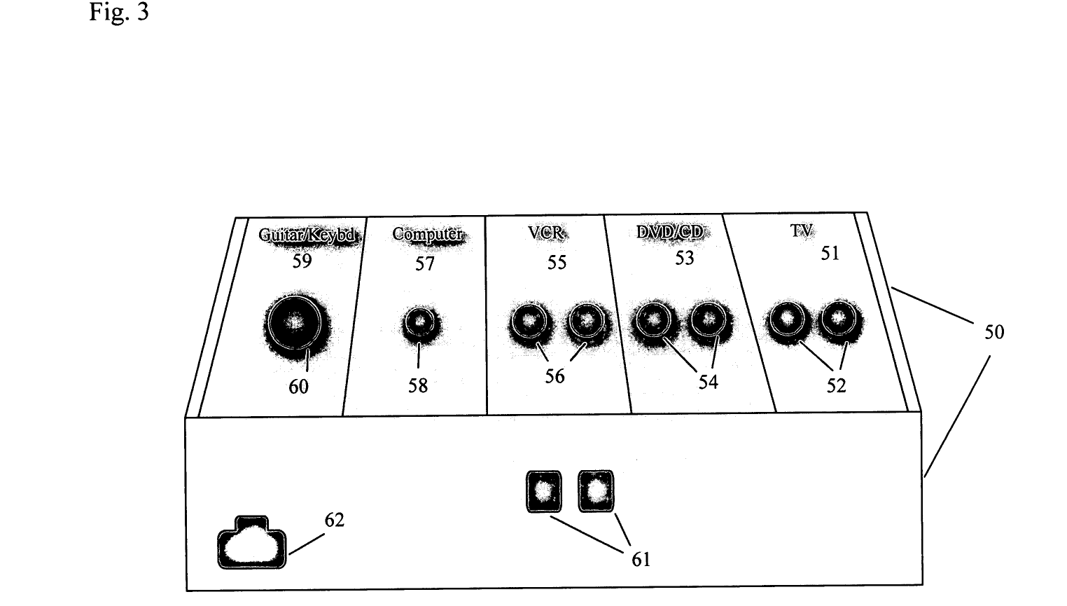

In FIG. 3,
50 is back panel.
51 is first component plug in area, TV in this drawing.
52 is first component audio cable inserts, RCA cable inserts for TV in this drawing.
53 is second component plug in area, DVD/CD player in this drawing.
54 is second component audio cable inserts, RCA cable inserts for DVD/CD player in this drawing.
55 is third component plug in area, VCR in this drawing.
56 is third component audio cable inserts, RCA cable inserts for VCR in this drawing.
57 is fourth component plug in area, Computer in this drawing.
58 is fourth component audio cable insert, 3.5 mm cable insert for Computer in this drawing.
59 is fifth component plug in area, Guitar/Keyboard in this drawing.
60 is fifth component audio cable insert, ¼ inch cord insert for Guitar/Keyboard in this drawing.
61 is speaker terminals
62 is AC power outlet

While the invention has been described in connection with a preferred embodiment, it is not intended to limit the scope of the invention to the particular form set forth, but on the contrary, it is intended to cover such alternatives, modifications, and equivalents as may be included within the spirit and scope of the invention as defined by the appended claims.

1. A machine for Audio/Video Stereo Receiver with Multiple Tone Controls that has features of:
a. Front panel that includes a number of component strips, in addition to the traditional functions such master volume control, balance control and system on/off switch.
b. Back panel that is partly slanted.

2. A machine for Audio/Video Stereo Receiver with Multiple Tone Controls as claimed in claim 1 wherein the front panel comprises specifically of master volume control, balance control, system power switch, AM/FM radio strip, and multiple columns of different component strips.

3. A machine for Audio/Video Stereo Receiver with Multiple Tone Controls as claimed in claim 2 wherein the AM/FM radio strip comprises of analog or digital display, tuning control, AM radio selection button, FM radio selection button, tone control buttons (treble and bass) and AM/FM radio strip on/off switch.

4. A machine for Audio/Video Stereo Receiver with Multiple Tone Controls as claimed in claim 2 wherein each of the multiple columns of different component strips has its own tone control buttons (treble and bass) and on/off switch.

5. A machine for Audio/Video Stereo Receiver with Multiple Tone Controls as claimed in claim 1 wherein the slanted area of the back panel has multiple columns of component connection plug-ins. Each component plug-in in the back panel is linked to the component strip straight forwardly located in the front panel.

6. A machine for Audio/Video Stereo Receiver with Multiple Tone Controls as claimed in claims 3 and 4 wherein on/off switch of each of the strips does not function exclusively of each other. If two (2) or more strip switches are pressed on simultaneously, sound signals from the pressed on strips are all transmitted to the receiver's main circuitry and to the loud speakers.

7. A machine for Audio/Video Stereo Receiver with Multiple Tone Controls as claimed in claim 1 wherein the not slanted, straight up area has AC power cord outlet.
